(19) United States
(12) Patent Application Publication
(10) Pub. No.: US 2007/0037347 A1
(43) Pub. Date: Feb. 15, 2007

(54) Capacitor of semiconductor device and method of fabricating the same

(75) Inventor: Sang-Su Kim, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/488,969

(22) Filed: Jul. 19, 2006

(30) Foreign Application Priority Data
Aug. 10, 2005 (KR) 10-2005-73448

(51) Int. Cl. H01L 21/8242

(52) U.S. Cl. 438/243

(57) ABSTRACT

A capacitor of a semiconductor device includes an oxide layer pattern including a trench formed on a semiconductor substrate, the trench having an inner wall and a bottom, quantum dots discontinuously formed on the inner wall of the trench, a bottom electrode formed on the inner wall and the bottom of the trench, the bottom electrode substantially surrounding the quantum dots, a dielectric layer formed on the bottom electrode, and a top electrode formed on the dielectric layer.

### CROSS-REFERENCE TO RELATED APPLICATION

This application claims priority to Korean Patent Application 2005-73448 filed on Aug. 10, 2005, the disclosure of which is incorporated by reference herein.

### BACKGROUND

1. Technical Field

The present disclosure relates to a semiconductor device and a method of fabricating the same, and more particularly to a capacitor of a semiconductor device and a method of fabricating the same.

2. Discussion of Related Art

In a semiconductor device, such as a dynamic random access memory (DRAM) having a unit memory cell comprising a capacitor and a transistor, increased cell capacitance can enhance the readout performance for the unit memory cell and can reduce soft error rates. As integration density in semiconductor devices increases, an area for the unit memory cell becomes smaller thereby reducing an area for the cell capacitor.

A cylindrical capacitor is used to increase the cell capacitance. A bottom electrode having a hemisphere-shaped grain (HSG) thereon is used to further increase the cell capacitance of the cylindrical capacitor. The HSG can increase a surface area of the bottom electrode of the cell capacitor. However, clotting HSGs may occur between neighboring bottom electrodes.

A metal-insulator-metal (MIM) capacitor in which metal layers are used as the top and bottom electrodes is used to increase the cell capacitance. The cell capacitance can increase by increasing a width of the cylinder in the cell capacitor. However, bridge defects can occur between adjacent cells. Alternatively, the cell capacitance can increase by increasing a height of the cylinder. However, the increased height may cause larger step differences with respect to peripheral circuits. Thus, processing margins of subsequent photolithography processes for, for example, metal contacts and interconnections may not be sufficient.

### SUMMARY OF THE INVENTION

Exemplary embodiments of the present invention provide a capacitor and method of fabricating a capacitor capable of increasing an area for the electrode of the capacitor.

According to an exemplary embodiment of the present invention, a capacitor of a semiconductor device comprises an oxide layer pattern including a trench on a semiconductor substrate, the trench having an inner wall and a bottom, quantum dots discontinuously formed on the inner wall of the trench, a bottom electrode formed on the inner wall and the bottom of the trench, the bottom electrode substantially surrounding the quantum dots, a dielectric layer formed on the bottom electrode, and a top electrode formed on the dielectric layer.

The quantum dots may comprise one of polysilicon, silicon nitride, and silicon oxide.

According to an exemplary embodiment of the present invention, a capacitor of a semiconductor device comprises a contact formed in an interlayer insulation layer, the contact connecting to an impurity region in a semiconductor substrate, an oxide layer pattern including a trench formed on the contact and the interlayer insulating layer, the trench having an inner wall and a bottom, quantum dots discontinuously formed on the inner wall and bottom of the trench, a bottom electrode formed on the inner wall and bottom of the trench and substantially surrounding the quantum dots, and a dielectric layer and a top electrode that are sequentially stacked on the oxide layer pattern and the bottom electrode.

According to an exemplary embodiment of the present invention, a method of fabricating a capacitor of a semiconductor device comprises forming an oxide layer pattern that includes a trench on a semiconductor substrate, the trench having an inner wall and a bottom, forming quantum dots on the inner wall and bottom of the trench, forming a bottom electrode on the inner wall and bottom of the trench, the bottom electrode substantially surrounding the quantum dots, forming a dielectric layer on the bottom electrode, and forming a top electrode on the dielectric layer.

### BRIEF DESCRIPTION OF THE DRAWINGS

Exemplary embodiments of the present disclosure can be understood in more detail from the following description taken in conjunction with the accompanying drawings of which:

FIG. 1 is a sectional view illustrating a capacitor of a semiconductor device in accordance with an exemplary embodiment of the invention; and

FIGS. 2 through 10 are sectional views illustrating a method for fabricating a capacitor of a semiconductor device in accordance with an exemplary embodiment of the present invention.

### DETAILED DESCRIPTION OF EXEMPLARY EMBODIMENTS

Exemplary embodiments of the present invention will be described in more detail with reference to the accompanying drawings. The present invention may, however, be embodied in many different forms and should not be construed as limited to the embodiments set forth herein.

FIG. 1 is a sectional view illustrating a capacitor of a semiconductor device in accordance with an exemplary embodiment of the invention.

Referring to FIG. 1, impurity regions 120a and 120b are disposed in a semiconductor substrate 100 including field isolation layers 110 that define active and field regions.

The impurity region 120a is electrically connected with a bit line (not shown), while the impurity region 120b is electrically connected with a bottom electrode of a capacitor. The impurity regions 120a and 120b can be used as source/drain regions of a transistor.

Between the impurity regions 120a and 120b, a gate pattern 130 is formed on the substrate 100. The gate pattern 130 may comprise, for example, a polysilicon layer, a metal layer, or combinations thereof.

On the semiconductor substrate 100, an interlayer insulation layer 140 is formed to isolate bit lines, contact pads, and transistors from each other. The interlayer insulation layer 140 may comprise, for example, a single layer of silicon nitride or silicon oxide, or combinations thereof.

Through the interlayer insulation layer 140, a contact 150 is formed to electrically connect the impurity region 120b with a capacitor. The contact 150 may comprise a conductive material such as, for example, tungsten (W), copper (Cu), or polysilicon.

Although not shown, a barrier layer may be disposed on both sidewalls to block diffusion of the conductive material toward the interlayer insulation layer 140.

An oxide layer pattern 210a including a trench 220 is formed on the interlayer insulation layer 140. The trench 220 exposes the contact 150 and the interlayer insulation layer 140 outside the contact 150. Between the oxide layer pattern 210a and the interlayer insulation layer 140 may be interposed an etch-stopping layer pattern 200a. The etch-stopping layer pattern 200a may comprise, for example, silicon nitride (SiN) or silicon oxynitride (SiON).

The oxide layer pattern 210a may comprise an oxide formed by, for example, a chemical vapor deposition (CVD). The oxide layer pattern 210a may comprise, for example, BPSG, HDP oxide, or a low-k oxide layer. The oxide layer pattern 210a may determine the height of the lower electrode and may have a thickness of about 9500 Å to about 12000 Å.

In an exemplary embodiment of the present invention, quantum dots 230 are 20 discontinuously formed on an inner wall 220a of the trench 220. The quantum dots 230 are provided to increase a surface area of the inner wall 220a in the trench 220. The quantum dots 230 may be generated by, for example, a CVD using silane (SiH₄) gas or mixture gas of dichlorosilane (DCS; SiHCl₂) and hydrogen (H₂).

The quantum dots 230 may comprise, for example, polysilicon, silicon nitride, or silicon oxide. The diameter of the quantum dots 230 can be about 2 nm to about 10 nm. In an exemplary embodiment of the present invention, the quantum dots 230 may be formed on the bottom 220b of the trench 220.

A bottom electrode 240a of the capacitor is formed on the inner wall 220a and the bottom 220b of the trench 220. The bottom electrode 240a substantially surrounds the quantum dots 230. Thus, the bottom electrode 240a has a rugged surface. The rugged surface increases a surface area of the bottom electrode 240a.

The bottom electrode 240a may comprise, for example, a polysilicon or metal layer. The metal layer may include, for example, titanium nitride (TiN) or ruthenium (Ru).

A dielectric layer 250 is formed on the oxide layer pattern 210a and the bottom electrode 240a. The dielectric layer 250 may comprise, for example, a silicon oxide layer, a silicon oxynitride layer, or a high-dielectric layer. The high-dielectric layer may comprise, for example, tantalum oxide (TaO), aluminum oxide (AlO), hafnium oxide (HfO), or combinations thereof.

The top electrode 260 is formed on the dielectric layer 250. The top electrode 260 may comprise, for example, a polysilicon or metal layer. The metal layer as the top electrode 260 may comprise, for example, titanium nitride (TiN) or ruthenium (Ru).

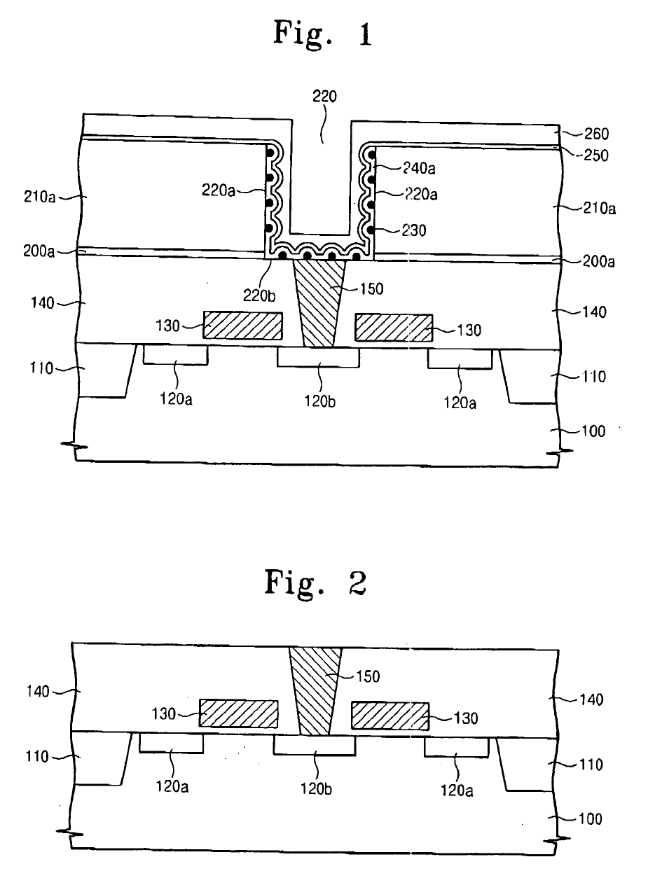

FIGS. 2 through 10 are cross-sectional views illustrating a method for forming a capacitor in accordance with an exemplary embodiment of the present invention.

Referring to FIG. 2, a field isolation layer 110 defining an active region is formed in a semiconductor substrate 100. The field isolation layer 110 may be formed by etching predetermined regions of the substrate 100 and filling the etched regions with an insulation material. In an alternative embodiment, the filed isolation layer 110 may be formed by local oxidation of the silicon substrate.

A gate pattern 130 is formed on the semiconductor substrate 100. The gate pattern 130 may comprise, for example, a single layer of polysilicon layer or a metal layer, or combinations of thereof.

Impurity ions are implanted into the semiconductor substrate 100 using the gate pattern 130 as a mask. Impurity regions 120a and 120b can be used as the source/drain of a cell transistor. In the case of an N-type cell transistor, impurity ions such as phosphorous (P) or arsenic (As) can be implanted.

Each of the impurity regions 120a and 120b may comprise low and high concentration impurity regions. For example, the impurity regions 120a and 120b may comprise a lightly doped drain (LDD).

In an exemplary embodiment of the present invention, the impurity regions 120a and 120b can be formed by a self-aligned ion implantation using the gate pattern 130 as a mask.

An interlayer insulation layer 140 is deposited on the gate pattern 130 and the semiconductor substrate 100. The interlayer insulation layer 140 may comprise various materials and heights. The interlayer insulation layer 140 may be a single layer or a multiple layer. In an exemplary embodiment of the present invention, the interlayer insulation layer 140 may include several components, such as, bit lines and contact pads.

After forming a hole (not shown) through the interlayer insulation layer 140 using, for example, a photolithography process, a contact 150 is formed by filling the hole with a conductive material such as, for example, tungsten (W), copper (Cu), or polysilicon. Before filling up the hole with the conductive material, a barrier layer (not shown) may be formed to prevent diffusion of the conductive material toward the interlayer insulation layer 140.

If the contact 150 comprises tungsten (W) as the conductive material, the barrier layer may comprise titanium (Ti), titanium nitride (TiN), or combinations thereof.

If the contact 150 comprises copper (Cu) as the conductive material, the barrier layer may comprise tantalum (Ta), tantalum nitride (TaN), or combinations thereof. The contact 150 may be connected directly or indirectly through a contact pad to the impurity region 120b in the semiconductor substrate 100.

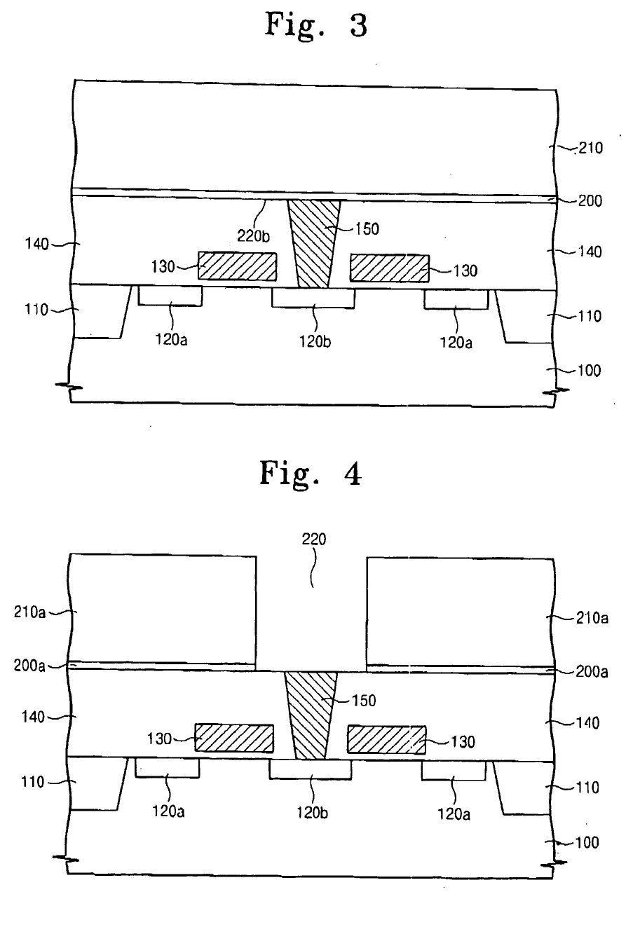

Referring to FIG. 3, an etch-stopping layer 200 and an oxide layer 210 are deposited in sequence on the interlayer insulation layer 140. The etch-stopping layer 200 can be used to protect the interlayer insulation layer 140 and the contact 150 from the etching process for forming a trench 220. The etch-stopping layer 200 may comprise silicon nitride (SiN) or silicon oxynitride (SiON).

The oxide layer 210 may comprise, for example, a borophospho-silicate glass (BPSG) layer, a high-density plasma (HDP) layer, or a low-k (low dielectric) layer by CVD. The height of the oxide layer 210 may be variable in accordance with the cell capacitance and processing quality required by the semiconductor device. The height of the oxide layer 210 can be about 9500 Å through about 12000 Å.

Referring to FIG. 4, the oxide layer 210 and the etch-stopping layer 200 are sequentially etched to form the trench 220. The trench 220 is sized in accordance with the cell capacitance and design rule required by the semiconductor device.

In an exemplary embodiment of the present invention, the etching process for the trench 220 includes etching the oxide layer 210 and etching the etch-stopping layer 200.

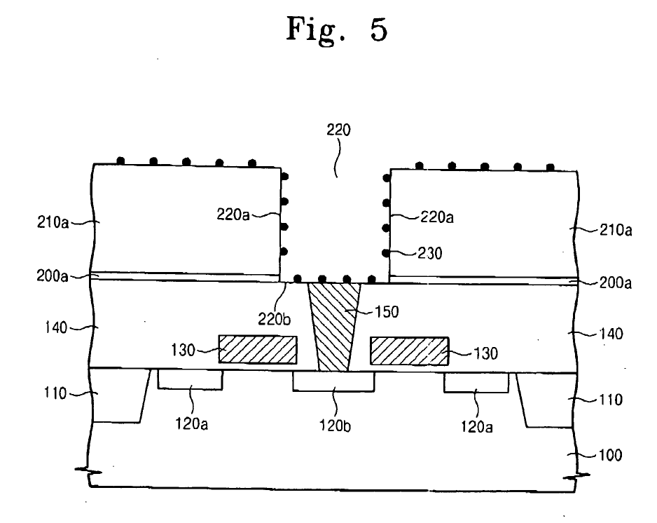

Referring to FIG. 5, a low-pressure CVD (LPCVD) can be performed with silane (Sir) gas or a mixture gas of dichlorosilane (DCS; SiH₂Cl₂) and hydrogen (H₂) to form the discontinuous quantum dots 230 on the oxide layer pattern 210a and the inner wall 220a and the bottom 220b of the trench 220. The quantum dots 230 may comprise, for example, polysilicon.

The quantum dots 230 can be formed with a diameter of about 2 nm through about 10 nm under the temperature of about 500° C. to about 600° C. In an exemplary embodiment of the present invention, the polysilicon quantum dots 230 may be oxidized to form silicon-oxide quantum dots. In an exemplary embodiment of the present invention, the polysilicon quantum dots 230 may be nitrified to form silicon-nitride quantum dots. The quantum dots 230 may comprise, for example, polysilicon, silicon oxide, or silicon nitride in correspondence with the operational characteristic and contact resistance of the semiconductor device.

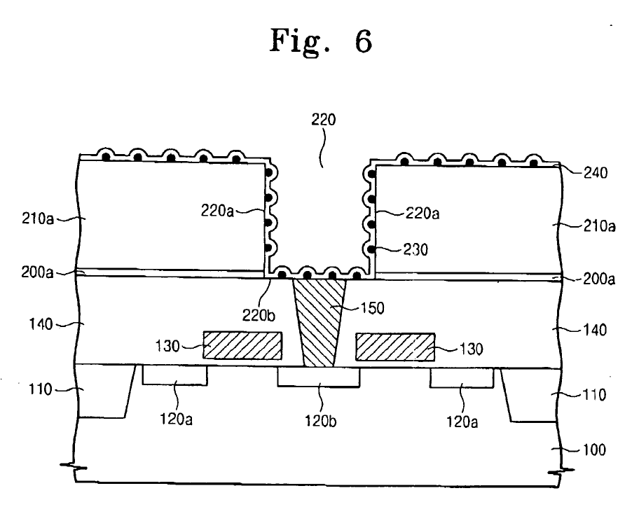

Referring to FIG. 6, a bottom electrode layer 240 is formed on the oxide layer pattern 210a including the inner wall 220a and the bottom 220b of the trench 220 such that the bottom electrode 240 substantially surrounds the quantum dots 230. Thus, the bottom electrode layer 240 has a rugged surface in accordance with an underlying structure of the quantum dots 230.

The bottom electrode layer 240 may comprise a polysilicon or metal layer. The metal layer can be a titanium nitride (TiN) or ruthenium (Ru) layer. In an exemplary embodiment of the present invention, the bottom electrode layer 240 can be deposited in the thickness of about 300 Å.

In an exemplary embodiment of the present invention, a cleaning process may be conducted to remove contaminants before depositing the bottom electrode layer 240.

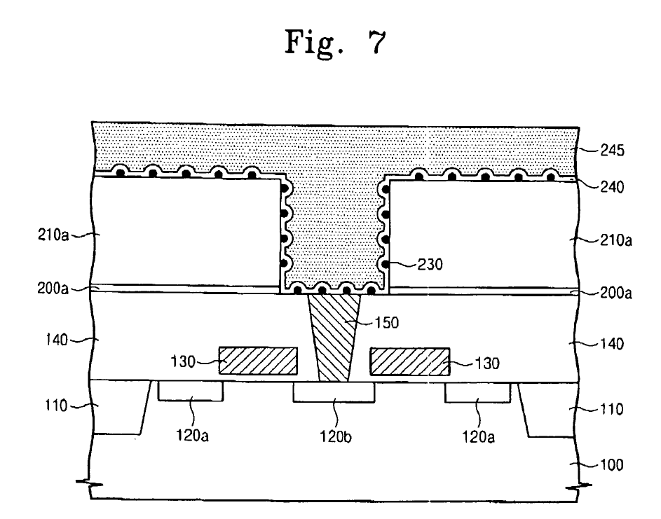

Referring to FIG. 7, a sacrificial layer 245 is deposited to fill the trench 220 for isolating the bottom electrode layer 240 and the quantum dots 230 from components of an adjacent memory cell. The sacrificial layer 245 may comprise, for example, silicon oxide or a material including photoresist.

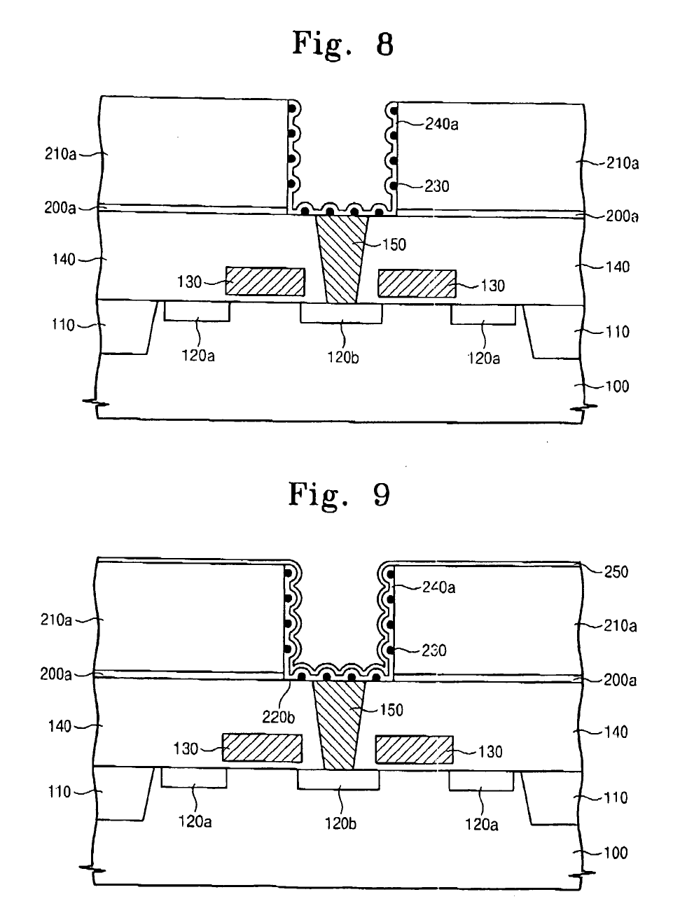

Referring to FIG. 8, a node separation process such as an etch-back or chemical/mechanical polishing (CMP) is conducted to remove the bottom electrode layer 240 and the quantum dots 230 outside the trench 220 and to form a bottom electrode 240a in the trench 220. During the node separation process, the upper portion of the oxide layer pattern 210a may be partially removed. The sacrificial layer 245 can be removed by an ashing or wet etching.

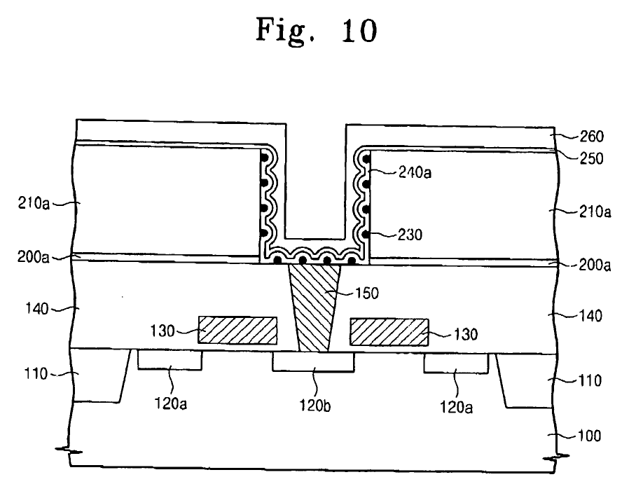

Referring to FIG. 9, the dielectric layer 250 is formed on the oxide layer pattern 210a and the bottom electrode 240a. In an exemplary embodiment of the present invention, the dielectric layer 250 may comprise a silicon oxide layer, a silicon oxynitride layer, or a high-dielectric layer. The high-dielectric layer may comprise tantalum oxide (TaO), aluminum oxide (AlO), hafnium oxide (HfO), or combinations thereof. In an exemplary embodiment of the present invention, a cleaning operation may be performed prior to the process of forming the dielectric layer 250.

Referring to FIG. 10, the top electrode 260 is formed on the dielectric layer 250.

In an exemplary embodiment of the present invention, the top electrode 260 may comprise, for example, a polysilicon layer or a metal layer. The metal layer as the top electrode 260 may comprise, for example, titanium nitride (TiN) or ruthenium (Ru). In an exemplary embodiment of the present invention, a cleaning operation may be performed prior to the process of forming the top electrode 260.

The capacitor of the semiconductor device according to an exemplary embodiment of the present invention can increase capacitance by extending the capacitive areas between the top and bottom electrodes using the discontinuous quantum dots.

Although exemplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A capacitor of a semiconductor device, comprising:
an oxide layer pattern including a trench on a semiconductor substrate, the trench having an inner wall and a bottom;
quantum dots discontinuously formed on the inner wall of the trench;
a bottom electrode formed on the inner wall and the bottom of the trench, the bottom electrode substantially surrounding the quantum dots;
a dielectric layer formed on the bottom electrode; and
a top electrode formed on the dielectric layer.

2. The capacitor of claim 1, wherein the quantum dots comprise polysilicon, silicon nitride, or silicon oxide.

3. The capacitor of claim 2, further comprising quantum dots formed on the bottom of the trench.

4. The capacitor of claim 2, further comprising:
an interlayer insulation layer between the semiconductor substrate and the oxide layer pattern, the interlayer insulation layer including a contact electrically connected to an impurity region of the semiconductor substrate.

5. The capacitor of claim 4, wherein the contact is connected with the bottom electrode in the trench.

6. The capacitor of claim 4, further comprising:
an etch-stopping layer between the oxide layer pattern and the interlayer insulation layer and having etch selectivity to the oxide layer pattern.

7. A capacitor of a semiconductor device, comprising:
a contact formed in an interlayer insulation layer, the contact being connected to an impurity region in a semiconductor substrate;
an oxide layer pattern including a trench formed on the contact and the interlayer insulation layer, the trench having an inner wall and a bottom;
quantum dots discontinuously formed on the inner wall and the bottom of the trench;
a bottom electrode formed on the inner wall and the bottom of the trench, the bottom electrode substantially surrounding the quantum dots; and
a dielectric layer and a top electrode being sequentially stacked on the oxide layer pattern and the bottom electrode.

8. The capacitor of claim 7, wherein the quantum dots comprise polysilicon, silicon nitride, or silicon oxide.

9. The capacitor of claim 8, wherein the bottom electrodes and the top electrodes comprise one of polysilicon and metal.

10. The capacitor of claim 9, wherein the metal includes one of titanium nitride and ruthenium.

11. The capacitor of claim 8, wherein the dielectric layer comprises one of a silicon oxide, silicon oxynitride, and high-dielectric layer.

12. The capacitor of claim 11, wherein the high-dielectric layer comprises one of tantalum oxide (TaO), aluminum oxide (AlO), hafnium oxide (HfO), and combinations thereof.

13. A method of fabricating a capacitor of a semiconductor device, the method comprising:
forming an oxide layer pattern including a trench on a semiconductor substrate, the trench having an inner wall and a bottom;
forming quantum dots on the inner wall and the bottom of the trench;
forming a bottom electrode on the inner wall and the bottom of the trench, the bottom electrode substantially surrounding the quantum dots;
forming a dielectric layer on the bottom electrode; and
forming a top electrode on the dielectric layer.

14. The method of claim 13, wherein the quantum dots comprise polysilicon quantum dots formed by a low-pressure CVD.

15. The method of claim 14, wherein the low-pressure CVD uses one of silane (SiH₄) gas and a mixture gas of dichlorosilane (DCS; SiHCl₂) and hydrogen (H₂).

16. The method of claim 14, wherein the polysilicon quantum dots are oxidized to form silicon-oxide quantum dots.

17. The method of claim 14, wherein the polysilicon quantum dots are nitrified to form silicon-nitride quantum dots.

18. The method of claim 13, wherein forming the bottom electrode comprises:
depositing a bottom electrode layer on the oxide layer pattern;
depositing a sacrificial layer on the oxide layer pattern to fill the trench;
etching the sacrificial layer and the bottom electrode layer outside the trench; and
removing a remaining sacrificial layer from the trench.

19. The method of claim 18, wherein etching the sacrificial layer and the bottom electrode layer outside the trench comprises one of an etch-back and a CMP operation.

20. The method of claim 18, wherein the sacrificial layer comprises a material including photoresist.
